(19) United States
(12) Patent Application Publication
(10) Pub. No.: US 2026/0136633 A1
(43) Pub. Date: May 14, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yao-Hsien Hsieh, Hsinchu (TW); Wei-Chau WANG, Hsinchu (TW)

(73) Assignee: Taiwan Semiconductor Manufacturing Company, Ltd., Hsinchu (TW)

(21) Appl. No.: 18/944,089

(22) Filed: Nov. 12, 2024

(51) Int. Cl. H01L 29/49; H01L 21/285; H01L 29/423

(52) U.S. Cl. CPC H10D 64/663; H10D 64/0112; H10D 64/514; H10D 64/517

(57) ABSTRACT

A semiconductor device including a substrate, a gate oxide layer, a polysilicon layer and a metal silicide layer is provided. The gate oxide layer is formed on the substrate. The polysilicon layer is formed on the gate oxide layer. The metal silicide layer is formed on the polysilicon layer. A ratio of silicon atoms to metal atoms in the metal silicide layer is less than or equal to 2.5.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device according to an embodiment of the present disclosure.

FIG. 2 is a graph plotting the silicon ratio in tungsten silicide (WSix) versus the thickness of the oxide capping layer.

FIGS. 3A and 3B are metallographic diagrams of silicon ratio in tungsten silicide (WSix) and corresponding grain size of WSix.

FIG. 4 is a graph illustrating the silicon ratio in tungsten silicide (WSix) versus the grain size of WSix.

FIGS. 5A and 5B respectively illustrate diagrams of the oxide capping layers with different thicknesses.

FIG. 5C is a graph illustrating the phosphorus concentration versus depth distance in the polysilicon layer.

FIG. 6A is a schematic diagram of a semiconductor device according to another embodiment of the present disclosure.

FIG. 6B is a schematic diagram of a semiconductor device according to another embodiment of the present disclosure.

FIGS. 7A to 7F are schematic diagrams of a method for manufacturing a semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Polycrystalline silicon (also called polysilicon, poly-Si) is often used to form gate electrodes of semiconductors due to its very high melting point similar to that of the silicon substrate. However, polycrystalline silicon has high resistance. Therefore, a metal silicide layer such as tungsten silicide (WSix) is deposited on top of the polysilicon layer to increase conductivity. The present disclosure proposes an improved semiconductor device, in which the gate electrode has a thicker oxide capping layer by controlling the silicon ratio in tungsten silicide (for example, x is less than or equal to 2.5), thereby improving the performance of the semiconductor device. For example, the ratio x of silicon atoms to tungsten atoms in tungsten silicide (WSix) is called the silicon ratio, and the silicon ratio x can be less than or equal to 2.5, such as 2.4, 2.3 or other ratio greater than 2.

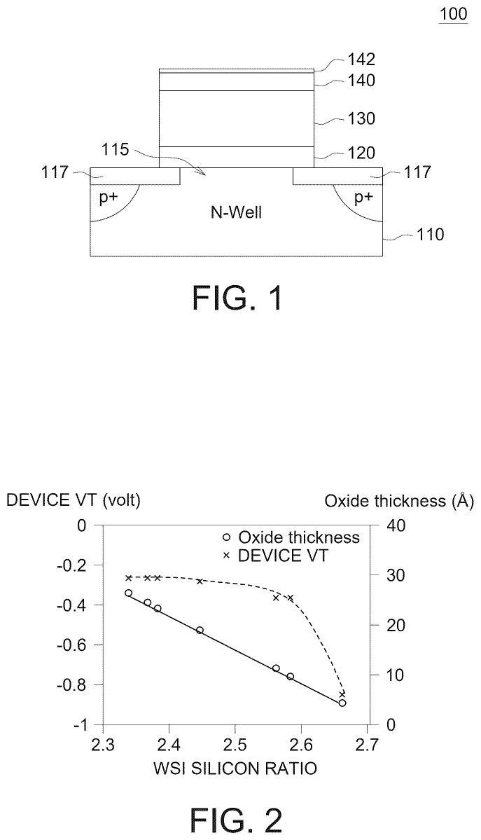

Referring to FIG. 1, a schematic diagram of a semiconductor device 100 according to an embodiment of the present disclosure is illustrated. The semiconductor device 100 is, for example, a metal oxide semiconductor (MOS) device, which includes a substrate 110, a gate oxide layer 120, a polysilicon layer 130, a metal silicide layer 140 and an oxide capping layer 142.

The substrate 110 may be a wafer made of any semiconductor material. The semiconductor material may include silicon, for example in the form of crystalline silicon or polycrystalline silicon. In alternative embodiments, the substrate 110 may be made from other elemental semiconductors such as germanium, or may include one of compound semiconductors such as silicon carbide (SiC), gallium arsenide (GaAs), indium arsenide (InAs), and indium phosphide (InP).

The gate oxide layer 120 is formed on the substrate 110. In some embodiments, the gate oxide layer 120 may be grown by thermal oxidation of substrate 110, such as in the presence of water or oxygen (O₂) at a temperature of about 850° C. to about 950° C. Alternatively, the gate oxide layer 120 may be formed by a chemical vapor deposition (CVD) process, such as using oxygen (O₂) together with silane (SiH₄) or dichlorosilane (SiH₂Cl₂) at high temperatures above about 600° C., or using tetrachlorosilane (TEOS). Depending on the desired application, the gate oxide layer 120 may have a thickness of about 30 Angstroms to about 550 Angstroms. In some embodiments, the gate oxide layer 120 has a thickness of about 60 Angstroms to about 120 Angstroms. The gate oxide layer 120 separates the gate electrode from the source and drain electrodes on the substrate 110. The gate oxide layer 120 is typically very thin compared to polysilicon layer 130. In one embodiment, the thickness of the gate oxide layer 120 may be less than 30 angstroms to further reduce the threshold voltage of the transistor.

The polysilicon layer 130 is formed on the gate oxide layer 120. In some embodiments, the polysilicon layer 130 may be formed using chemical vapor deposition (CVD) or physical vapor deposition (PVD), such as sputtering methods. For example, SiH₄ may decompose at a temperature of about 500° C. to about 800° C. to form the polysilicon layer 130. The polysilicon layer 130 may have a thickness of about 500 Angstroms to about 5000 Angstroms. In some embodiments, the polysilicon layer 130 has a thickness of about 800 Angstroms to about 2500 Angstroms.

In the semiconductor device 100, since the polysilicon layer 130 has heat-resistant properties, when making a metal oxide semiconductor (MOS) transistor, polycrystalline silicon material is usually used as the gate electrode of the transistor, so that the source and drain regions on the substrate 110 can be annealed together at high temperatures. Secondly, since the polysilicon layer 130 can block atoms doped by ion implantation from entering the channel region, self-aligned source and drain regions can be easily formed after gate patterning. In addition, when the polysilicon layer 130 is biased, it lacks carriers, so that a depletion region is easily generated near the interface between the polysilicon layer 130 and the gate oxide layer 120. This depletion effect will not only increase the equivalent thickness of the gate oxide layer 120, but also cause the gate capacitance to decrease, thereby leading to problems such as a decline in device driving capability.

The threshold voltage of a MOSFET is mainly determined by the difference between the work functions of the gate and channel materials. Since the polysilicon layer 130 is essentially a semiconductor, it can be doped with different impurities to change its work function. More importantly, because the energy gap between the polysilicon layer 130 and the underlying silicon used as a channel region is the same, the requirements can be achieved by directly adjusting the work function of the polysilicon layer 130 to reduce the threshold voltage of PMOS or NMOS transistor.

However, since the polysilicon layer 130 is formed of a semiconductor material with a higher resistance value and is not doped with impurities (such as N-type dopants) or has impurities with a low doping concentration, the polysilicon layer 130 formed with the metal silicide layer 140 has better conductive properties and can withstand high-temperature processes. In addition, since the metal silicide layer 140 is located on the surface of the polycrystalline silicon layer 130 and is far away from the channel region, it will not have a great impact on the threshold voltage of the MOSFET.

The metal silicide layer 140, such as tungsten silicide, is formed on the polysilicon layer 130 to increase electrical conductivity. In some embodiments, a CVD process may be used to form tungsten silicide (WSix). Dichlorosilane (SiH₂Cl₂) and tungsten hexafluoride (WF₆) are commonly used as process gases and the combination reaction of gases occurs at a temperature of about 500° C. to about 600° C. The deposited tungsten silicide (WSix) can then be annealed to increase the conductivity of the tungsten silicide. Tungsten silicide (WSix) may have a thickness of about 500 Angstroms to about 5000 Angstroms. In some embodiments, tungsten silicide (WSix) has a thickness of about 800 Angstroms to about 2000 Angstroms.

Finally, the oxide capping layer 142 is formed on the metal silicide layer 140. In some embodiments, oxide capping layer 142 may be formed using known oxidation methods. Typically, the oxide capping layer 142 is grown on the surface of the metal silicide layer 140 at a temperature of about 300° C. to about 650° C. The oxide capping layer 142 may have any desired thickness, such as in the range of about 10 Angstroms to about 100 Angstroms. In some embodiments, the oxide capping layer 142 has a thickness of about 20 Angstroms to about 60 Angstroms.

In some embodiments, the thickness of the oxide capping layer 142 is related to the silicon ratio in the metal silicide layer 140, and a thicker oxide capping layer 142 can be generated by controlling the silicon ratio in the tungsten silicide (for example, x is less than or equal to 2.5) to further improve the performance of the semiconductor device 100. Please refer to FIG. 2, which is diagram illustrating the silicon ratio in tungsten silicide (WSix) versus the thickness of the oxide capping layer 142. As shown in FIG. 2, taking the silicon ratio x in tungsten silicide (WSix) as the horizontal axis and taking the thickness of the oxide capping layer 142 as the vertical axis (at right side), it can be obtained that the greater the silicon ratio x, the thinner the oxide capping layer 142. In order to avoid the thickness of the oxide capping layer 142 being too thin, the silicon ratio x in the tungsten silicide is controlled, for example, to be less than or equal to 2.5, so that the thickness of the oxide capping layer 142 is greater than or equal to about 30 angstroms.

In addition, FIG. 2 also illustrates the silicon ratio x in tungsten silicide (WSix) and the threshold voltage (VT) of the gate electrode. As shown in FIG. 2, taking the silicon ratio x in tungsten silicide (WSix) as the horizontal axis and taking the threshold voltage of the gate electrode as the vertical axis (at left side, negative value), it can be obtained that the greater the silicon ratio x, the greater the absolute value of the threshold voltage of the gate electrode. In order to avoid the threshold voltage of the gate electrode being too high, the silicon ratio x in the tungsten silicide is controlled, for example, to be less than or equal to 2.5, so that the absolute value of the threshold voltage of the gate electrode is less than about 0.7V. In some embodiments, the absolute value of the threshold voltage of the gate electrode is less than 0.27V, for example.

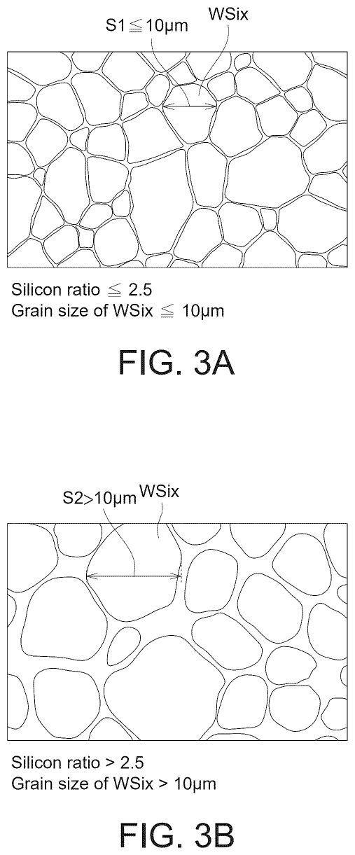

Referring to FIG. 3A and FIG. 3B, the metallographic diagrams of the silicon ratio x and the corresponding grain size S in tungsten silicide (WSix) are illustrated. In FIG. 3A, when the silicon ratio x in tungsten silicide (WSix) is less than or equal to 2.5, tungsten silicide has a smaller grain size S1, the crystals are arranged neatly, and the lattice gap between crystals is small. However, In FIG. 3B, when the silicon ratio x in tungsten silicide (WSix) is greater than 2.5, tungsten silicide has a larger grain size S2, the crystal arrangement is scattered, and the lattice gap between crystals is larger. Since the reduction of the grain size of tungsten silicide will increase the oxidation reaction area of tungsten silicide, by controlling the silicon ratio x in tungsten silicide (WSix) to be less than or equal to 2.5, tungsten silicide can have a smaller grain size S1, for example less than 10 microns, and at the same time, the thickness of the oxide capping layer 142 can be increased because the oxidation reaction area of tungsten silicide is increased.

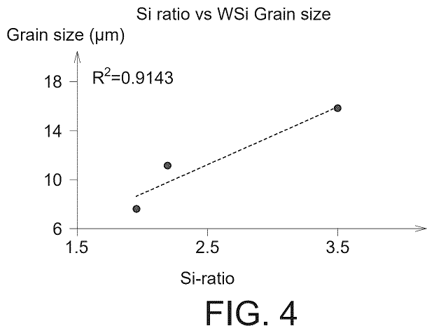

As shown in FIG. 4, the silicon ratio x in tungsten silicide (WSix) is substantially proportional to the grain size of tungsten silicide. Through regression analysis, it can be obtained that R square is approximately 0.9143. The greater the R square, the better the fit of the regression model.

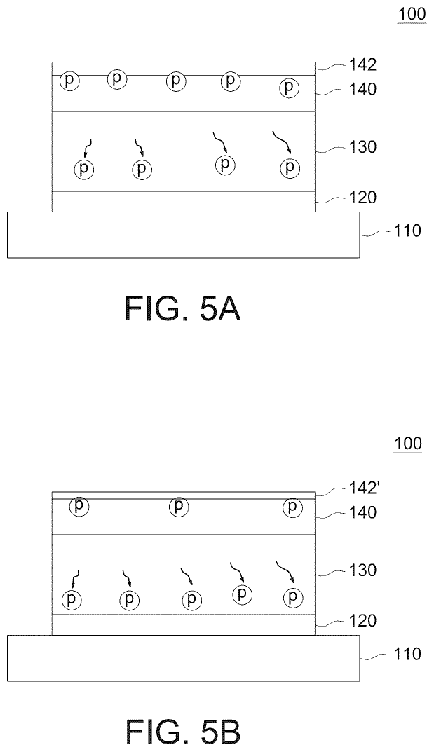

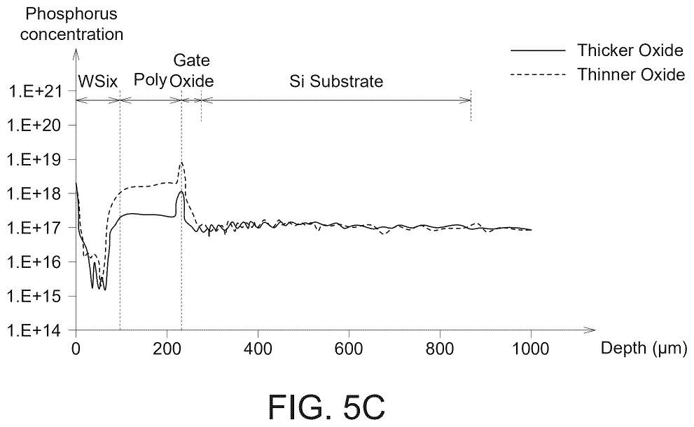

Referring to FIGS. 5A and 5B, schematic diagrams of the oxide capping layers 142 and 142′ with different thicknesses are respectively illustrated. In FIG. 5A, when the silicon ratio x in tungsten silicide (WSix) is less than or equal to 2.5, the grain size of tungsten silicide decreases and the oxidation reaction area of tungsten silicide increases, thereby enhancing the capability of species trapping under well controlling (more phosphorus atoms are trapped). In FIG. 5B, when the silicon ratio x in tungsten silicide (WSix) is greater than 2.5, the grain size of tungsten silicide increases and the oxidation reaction area of tungsten silicide decreases, the thickness of the oxide capping layer 142′ is relatively thin, thereby degrading the capability of species trapping under well controlling (less phosphorus atoms are trapped).

Referring to FIG. 5C, the relationship between the phosphorus concentration and the depth distance in the polysilicon layer 130 is illustrated. In FIG. 5C, secondary ion mass spectroscopy (SIMS) profiles for phosphorus concentration in the semiconductor device with thicker or thinner oxide film are shown. The phosphorus redistribution and its chemical structure can be investigated using X-ray photoelectron spectroscopy (XPS) or SIMS. The in-depth profiles of phosphorus obtained by SIMS show that the dopant-P redistributed in the gate oxide film/Si-substrate interface are different. The phosphorus concentration with higher and gradient increase is shown for thinner oxide capping layer 142′ (see broken line), while the phosphorus concentration with flat and stable threshold voltage is shown for thicker oxide capping layer 142 (see solid line), which have better capability of species trapping under well controlling.

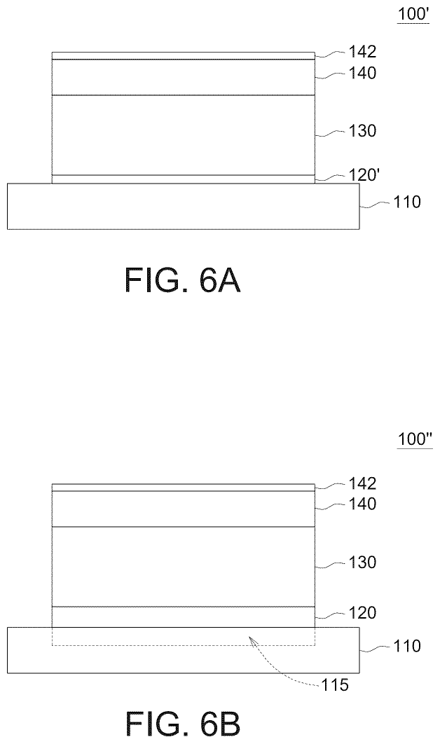

Referring to FIG. 6A, a schematic diagram of a semiconductor device 100′according to another embodiment of the present disclosure is illustrated. The semiconductor device 100′is, for example, a metal oxide semiconductor (MOS) device, which includes a substrate 110, a gate oxide layer 120′, a polysilicon layer 130, a metal silicide layer 140 and an oxide capping layer 142. The present disclosure provides an improved semiconductor device 100′in which the thickness of the gate oxide layer 120′is less than 30 Angstroms to further reduce the threshold voltage (VT) of the transistor. As the thickness of the gate oxide layer 120′ becomes thinner (for example, from 70 angstroms to 30 angstroms), the capacitance of the gate oxide layer 120′ increases relatively to control switching speed of the integrated circuit with low threshold voltage. The materials and manufacturing methods of the substrate 110, the gate oxide layer 120′, the polysilicon layer 130, the metal silicide layer 140 and the oxide capping layer 142 have been described above and will not be described again.

Referring to FIG. 6B, a schematic diagram of a semiconductor device 100″ according to another embodiment of the present disclosure is illustrated. The semiconductor device 100″ is, for example, a metal oxide semiconductor (MOS) device, which includes a substrate 110, a gate oxide layer 120, a polysilicon layer 130, a metal silicide layer 140 and an oxide capping layer 142. The present disclosure provides an improved semiconductor device 100″ that changes the doping concentration of the channel region 115 under the gate oxide layer 120. Taking a PMOS transistor as an example, the boron doping concentration of the channel region 115 under the gate oxide layer 120 ranging from 0 to 20 nm is, for example, less than about 5×10¹⁷ atoms/cm³ to achieve unusual low voltage (i.e., less than 0.27V) instead of nominal threshold voltage and have better IDD performance.

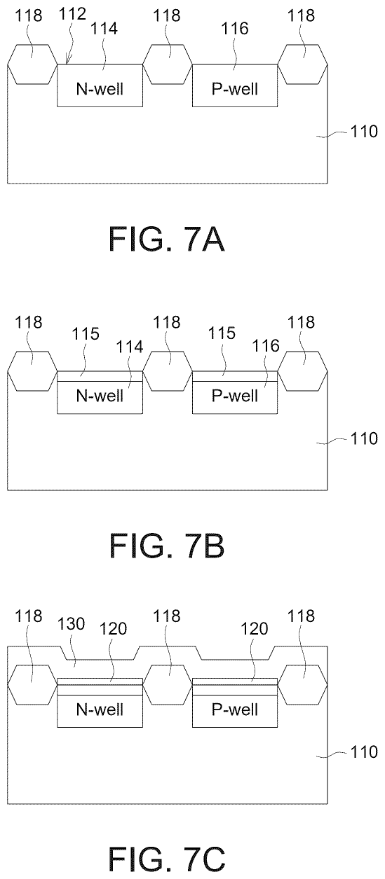

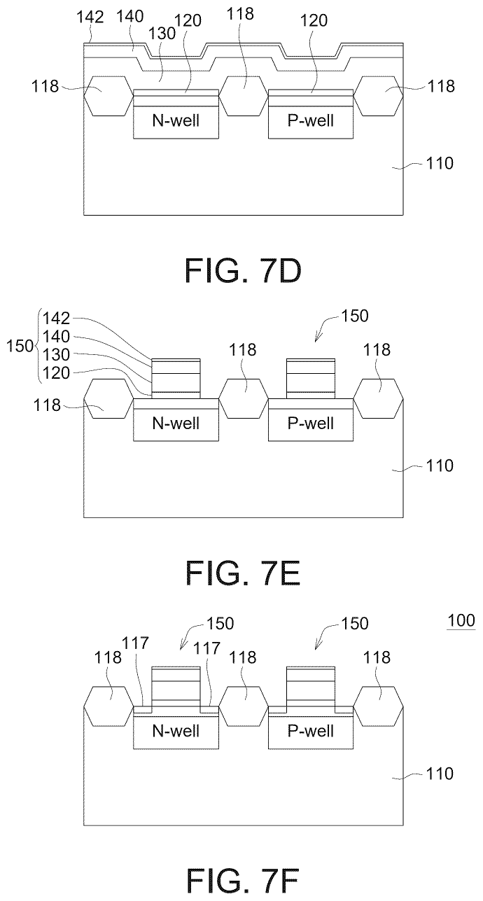

Next, referring to FIGS. 7A to 7F, schematic diagrams of a manufacturing method of a semiconductor device 100 according to an embodiment of the present disclosure are illustrated. First, a substrate 110 is provided, such as a silicon substrate, a silicon-containing substrate, or a silicon-on-insulator (SOI) substrate. At least one first transistor region 114 and at least one second transistor region 116 may be defined on the substrate surface 112. The first transistor region 114 and the second transistor region 116 may be used to form circuit elements such as NMOS transistors, PMOS transistors, and/or complementary metal oxide semiconductor (CMOS) transistors. In this embodiment, for example, the first transistor region 114 and the second transistor region 116 can be used to fabricate an NMOS transistor and a PMOS transistor respectively.

Next, a process such as local oxidation (LOCOS) or shallow trench isolation (STI) is used to fabricate a plurality of isolation structures 118 on the substrate surface 112 between the first transistor region 114 and the second transistor region 116. The isolation structure 118, such as a field oxide layer or a shallow trench isolation structure, surrounds and isolates the circuit elements in the first transistor region 114 and the second transistor region 116.

Next, in FIG. 7B, ions are implanted on the substrate surface 112 of the first transistor region 114 and the second transistor region 116 to adjust the doping concentration in the channel region 115. Dopants for p-type materials include, for example, boron. Dopants of n-type materials include, for example, phosphorus, arsenic, and antimony. The doping concentration may range from 10¹⁴ atoms/cm³ to 10²² atoms/cm³, such as a p+/n+ material having a concentration higher than about 10¹⁸/cm³. Some other concentration ranges may be used, such as n−−/p−− materials with doping concentrations less than 10¹⁴ atoms/cm³, n−/p− materials with doping concentrations ranging from 10¹⁴ atoms/cm³ to 10¹⁶ atoms/cm³, n/p materials with doping concentrations ranging from 10¹⁶ atoms/cm³ to 10¹⁸ atoms/cm³, n+/p+ materials having doping concentrations ranging from 10¹⁸ atoms/cm³ to 10²⁰ atoms/cm³, and n++/p++ materials with doping concentrations in the range greater than 10²⁰ atoms/cm³.

Next, in FIG. 7C, a gate oxide layer 120 is formed on the substrate surface 112 of the first transistor region 114 and the second transistor region 116. For example, in this embodiment, the fabrication of the gate oxide layer 120 may include using a high-temperature thermal oxidation or a chemical vapor deposition (CVD) process to form an oxide layer on the substrate surface 112 of the first transistor region 114 and the second transistor region 116. The gate oxide layer 120 is, for example, silicon dioxide or a high-k material layer. The high-k material layer may include, for example, hafnium silicate oxide (HfSiO), hafnium silicate oxynitride (HfSiON), hafnium oxide (HfO), lanthanum oxide (LaO), lanthanum aluminate (LaAlO), zirconium oxide (ZrO), zirconium oxysilicate (ZrSiO), hafnium zirconate (HfZrO) and other high dielectric constant dielectric layers or their combinations.

Next, a polysilicon layer 130 is grown on the gate oxide layer 120. The polysilicon layer 130 is, for example, formed of a semiconductor material and is not doped with impurities (such as N-type dopants) or has low doping concentration to achieve a low threshold voltage (i.e., less than 0.27V).

Next, in FIG. 7D, a metal silicide layer 140, such as tungsten silicide, is formed on the polysilicon layer 130 to increase conductivity. Afterwards, an oxide capping layer 142 is formed on the metal silicide layer 140. The thickness of the oxide capping layer 142 is related to the silicon ratio in the metal silicide layer 140. By controlling the silicon ratio in the metal silicide layer 140 (for example, less than or equal to 2.5), a thicker oxide capping layer 142 can be generated, thereby improving the performance of the semiconductor device 100.

Next, in FIG. 7E, an etching process is performed to remove part of the gate oxide layer 120, the polysilicon layer 130, the metal silicide layer 140 and the oxide capping layer 142 to define the width of the gate structure 150. The channel length of the MOS transistor is defined by the width of the gate structure 150. The polysilicon layer 130 completely covers the gate oxide layer 120, and the gate structure overlaps a portion of the drain region or a portion of the source region.

In FIG. 7F, lightly doped regions 117 are formed in the substrate 110 and located on both sides of the gate structure 150. In some embodiments, lightly doped region 117 is formed in a well region of substrate 110. The lightly doped region 117 may be formed by performing an ion implantation process known in the art at a tilt angle of about 30 to about 45 degrees. Since the polysilicon layer 130 can block the atoms doped by ion implantation from entering the channel region 115, self-aligned source and drain regions can be easily formed on both sides of the channel region 115 after gate patterning. In some embodiments, for NMOS transistors, the width of gate structure 150 ranges from about 0.35 μm to about 0.4 μm. For PMOS transistors, the width of the gate structure ranges from about 0.3 μm to about 0.35 μm.

The present disclosure relates to a semiconductor device and a manufacturing method thereof, in which the gate electrode has a thicker oxide capping layer by controlling the silicon ratio in tungsten silicide (for example, less than or equal to 2.5), thereby improving the performance of the semiconductor device. In addition, in order to avoid the threshold voltage of the gate electrode being too high, the silicon ratio in the tungsten silicide is controlled to be less than or equal to 2.5, so that the absolute value of the threshold voltage of the gate electrode can be controlled to be less than about 0.7V, such as 0.27V to improve switching speed of the integrated circuit with low threshold voltage.

According to some embodiments of the present disclosure, a semiconductor device including a substrate, a gate oxide layer, a polysilicon layer and a metal silicide layer is provided. The gate oxide layer is formed on the substrate. The polysilicon layer is formed on the gate oxide layer. The metal silicide layer is formed on the polysilicon layer. A ratio of silicon atoms to metal atoms in the metal silicide layer is less than or equal to 2.5.

According to some embodiments of the present disclosure, a semiconductor device including a substrate, a gate oxide layer, a polysilicon layer and a metal silicide layer is provided. The gate oxide layer is formed on the substrate. The polysilicon layer is formed on the gate oxide layer. The metal silicide layer is formed on the polysilicon layer. The oxide capping layer is formed on the metal silicide layer. A ratio of silicon atoms to metal atoms in the metal silicide layer is positively correlated with a grain size of the metal silicide layer.

According to some embodiments of the present disclosure, a method for manufacturing a semiconductor device is provided, including the following steps. A gate oxide layer is formed on a substrate. A polysilicon layer is formed on the gate oxide layer. The polysilicon layer is not doped with n-type or p-type impurities. A metal silicide layer is formed on the polysilicon layer. A ratio of silicon atoms to metal atoms in the metal silicide layer is less than or equal to 2.5. An oxide capping layer is formed on the metal silicide layer, wherein the thickness of the oxide capping layer is related to a ratio of silicon atoms to metal atoms in the metal silicide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate oxide layer configured to be formed on the substrate;
a polysilicon layer configured to be formed on the gate oxide layer; and
a metal silicide layer configured to be formed on the polysilicon layer,
wherein a ratio of silicon atoms to metal atoms in the metal silicide layer is less than or equal to 2.5.

2. The semiconductor device of claim 1, wherein a grain size of the metal silicide layer is less than or equal to 10 microns.

3. The semiconductor device of claim 1, wherein the gate oxide layer has a thickness less than 30 Angstroms.

4. The semiconductor device of claim 1, wherein the polysilicon layer is not doped with n-type or p-type impurities.

5. The semiconductor device of claim 1, wherein the polysilicon layer has a thickness between 800 angstroms and 2500 angstroms.

6. The semiconductor device of claim 1, wherein the metal silicide layer has a thickness between 800 angstroms and 2000 angstroms.

7. The semiconductor device of claim 1, further comprising an oxide capping layer configured to be formed on the metal silicide layer, the oxide capping layer having a thickness of 20 angstroms to 60 angstroms.

8. The semiconductor device of claim 7, wherein the thickness of the oxide capping layer is related to the ratio of silicon atoms to metal atoms in the metal silicide layer.

9. A semiconductor device, comprising:
a substrate;
a gate oxide layer configured to be formed on the substrate;
a polysilicon layer configured to be formed on the gate oxide layer; and
a metal silicide layer configured to be formed on the polysilicon layer,
wherein a ratio of silicon atoms to metal atoms in the metal silicide layer is positively correlated with a grain size of the metal silicide layer.

10. The semiconductor device of claim 9, wherein the ratio of silicon atoms to metal atoms in the metal silicide layer is less than or equal to 2.5.

11. The semiconductor device of claim 9, wherein the grain size of the metal silicide layer is less than or equal to 10 microns.

12. The semiconductor device of claim 9, wherein the gate oxide layer has a thickness less than 30 Angstroms.

13. The semiconductor device of claim 9, wherein the polysilicon layer is not doped with n-type or p-type impurities.

14. The semiconductor device of claim 9, wherein the polysilicon layer has a thickness between 800 angstroms and 2500 angstroms.

15. The semiconductor device of claim 9, wherein the metal silicide layer has a thickness between 800 angstroms and 2000 angstroms.

16. The semiconductor device of claim 9, further comprising an oxide capping layer configured to be formed on the metal silicide layer, the oxide capping layer having a thickness of 20 angstroms to 60 angstroms.

17. The semiconductor device of claim 16, wherein the thickness of the oxide capping layer is related to the ratio of silicon atoms to metal atoms in the metal silicide layer.

18. A method for manufacturing a semiconductor device, comprising:
forming a gate oxide layer on a substrate;
forming a polysilicon layer on the gate oxide layer, wherein the polysilicon layer is not doped with n-type or p-type impurities;
forming a metal silicide layer on the polysilicon layer, wherein a ratio of silicon atoms to metal atoms in the metal silicide layer is less than or equal to 2.5; and
forming an oxide capping layer on the metal silicide layer, wherein a thickness of the oxide capping layer is related to the ratio of silicon atoms to metal atoms in the metal silicide layer.

19. The method of claim 18, wherein the metal silicide layer is formed by using dichlorosilane (SiH₂Cl₂) and tungsten hexafluoride (WF₆) as process gases.

20. The method of claim 18, wherein the ratio of silicon atoms to metal atoms in the metal silicide layer is positively correlated with a grain size of the metal silicide layer.
